(19) United States
(12) Patent Application Publication
(10) Pub. No.: US 2026/0101704 A1
(43) Pub. Date: Apr. 9, 2026

(54) AUTOMATED CONTROL OF PROCESS CHAMBER COMPONENTS

(71) Applicant: Lam Research Corporation, Fremont, CA (US)

(72) Inventors: Kapil Sawlani, West Linn, OR (US); Paul Franzen, West Linn, OR (US); Patging John Elsworth Martin, Portland, OR (US)

(21) Appl. No.: 19/115,160

(22) PCT Filed: Sep. 20, 2023
(86) PCT No.: PCT/US2023/033209

§ 371 Date: Mar. 26, 2025

Related U.S. Application Data
(60) Provisional application No. 63/377,092, filed on Sep. 26, 2022.

(51) Int. Cl. H10P 72/00; C23C 16/505; C23C 16/52; H10P 14/60; H10P 74/20

(52) U.S. Cl. CPC H10P 72/0604; C23C 16/505; C23C 16/52; H10P 14/6336; H10P 72/0418; H10P 72/0462; H10P 74/203

(57) ABSTRACT

Methods, systems, and media for deposition control in a process chamber are provided. In some embodiments, a method comprises (a) obtaining, at a present time, information indicating a status of one or more components of the process chamber during performance of a deposition process on one or more wafers. The method may comprise (b) determining whether adjustments to one or more control components of the process chamber are to be made by providing an input based on the obtained information to a trained machine learning model configured to determine adjustments as an output, wherein the adjustments to the one or more control components cause a change in the deposition process. The method may comprise (c) transmitting instructions to a controller of the process chamber that cause the adjustments to the one or more control components to be implemented.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Multi-station process chambers may suffer from imbalances between stations of a multi-station process chamber. For example, there may be differences in gas flow, power transferred, etc. to the different stations. Such imbalances may cause undesired differences in substrates undergoing fabrication in the different stations. For example, there may be differences in deposition thicknesses, etch depths, etc. Moreover, utilizing each station in the same way may be an inefficient use of resources. Accordingly, it is desirable to individually control components of different stations of a multi-station process chamber.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Systems, apparatuses, and methods for automated control of multi-station process chamber components are provided.

In some embodiments, a method comprises (a) obtaining, at a present time, information indicating a status of one or more components of the process chamber during performance of a deposition process on one or more wafers, wherein the deposition process comprises a plurality of deposition cycles performed in the process chamber. The method comprises (b) determining whether adjustments to one or more control components of the process chamber are to be made by providing an input based on the obtained information to a trained machine learning model configured to determine adjustments as an output, wherein the adjustments to the one or more control components cause a change in the deposition process. The method comprises (c) responsive to determining that adjustments to the one or more control components are to be made, transmitting instructions to a controller of the process chamber that cause the adjustments to the one or more control components to be implemented. The method comprises (d) repeating (a)-(c) until the deposition process has been completed.

In some examples, the process chamber is a multi-station process chamber. In some examples, the adjustments to the one or more control components cause a change in the deposition process occurring in a first station of the multi-station process chamber relative to a second station of the multi-station process chamber. In some examples, in (d), (a)-(c) are repeated until the deposition process has been completed in each station of the multi-station process chamber.

In some examples, the process chamber is a single station process chamber.

In some examples, the machine learning model is configured to determine the adjustments based at least in part on a determination of predicted wafer characteristics of the one or more wafers undergoing the deposition process at the present time. In some examples, the predicted characteristics of the one or more wafers comprise a deposition thickness of each of the one or more wafers.

In some examples, determining whether adjustments to the one or more control components of the process chamber are to be made comprises comparing the predicted characteristics for a given wafer to target characteristics for the given wafer. In some examples, the predicted characteristics comprise virtual metrology measurements.

In some examples, the one or more components of the process chamber comprise one or more valves associated with one or more manifolds of the process chamber, each manifold configured to flow gas to a station of the process chamber. In some examples, the information indicating the status comprises a duration of time each of the one or more valves was open. In some examples, the input based on the obtained information provided to the trained machine learning model comprises an amount of gas provided to a given station operatively coupled to a manifold of the one or more manifolds based on the duration of time a corresponding valve was open. In some examples, the method further comprises determining the amount of gas based on the duration of time the corresponding valve was open and a gas flow rate.

In some examples, the trained machine learning model is configured to take as input at least one of: chamber pressure information; gas pressure information; ampoule temperature; non-ampoule gas feed; or carrier gas flow rate.

In some examples, obtaining the information in (a) occurs at a sampling rate greater than about 100 Hz.

In some examples, the one or more control components comprise one or more divert valves that divert gas flowed through a manifold from a station of the process chamber.

In some examples, the process chamber is a multi-station process chamber, and wherein the adjustments to the one or more control components comprise lowering a flow rate of gas to the first station relative to the flow rate of the gas to the second station.

In some examples, the process chamber is a multi-station process chamber comprising at least a first station and a second station, and wherein the adjustments to the one or more control components comprise changing a radio frequency (RF) power used to generate a plasma associated with the deposition process for the first station relative to the second station.

In some examples, the method further comprises: (e) obtaining post-processing metrology data on at least one wafer of the one or more wafers; and (f) updating the trained machine learning model using the post-processing metrology data. In some examples, the post-processing metrology data comprises at least one of: resistivity data; a mass of thin film grown for the at least one wafer; Fourier-transform infrared (FTIR) spectroscopy peaks; thickness of deposited film on the at least one wafer; refractive index; stress at localized positions on the at least one wafer; stress associated with wafer bow of the at least one wafer; particle information; or material permittivity information.

In some examples, the method further comprises: (e) determining, based on the predicted characteristics, a degradation status of at least one component of the one or more components of the process chamber. According to some embodiments, a computer program product comprising non-transitory computer readable media on which is provided computer executable instructions is provided. The instructions may comprise instructions for: (a) obtaining, at a present time, information indicating a status of one or more components of the process chamber during performance of a deposition process on one or more wafers, wherein the deposition process comprises a plurality of deposition cycles performed in the process chamber; (b) determining whether adjustments to one or more control components of the process chamber are to be made by providing an input based on the obtained information to a trained machine learning model configured to determine adjustments as an output, wherein the adjustments to the one or more control components cause a change in the deposition process; (c) responsive to determining that adjustments to the one or more control components are to be made, transmitting instructions to a controller of the process chamber that cause the adjustments to the one or more control components to be implemented; and (d) repeating (a)-(c) until the deposition process has been completed.

In some examples, the process chamber is a multi-station process chamber. In some examples, the adjustments to the one or more control components cause a change in the deposition process occurring in a first station of the multi-station process chamber relative to a second station of the multi-station process chamber. In some examples, in (d), (a)-(c) are repeated until the deposition process has been completed in each station of the multi-station process chamber In some examples, the process chamber is a single station process chamber.

In some examples, the machine learning model is configured to determine the adjustments based at least in part on a determination of predicted wafer characteristics of the one or more wafers undergoing the deposition process at the present time. In some examples, the predicted characteristics of the one or more wafers comprise a deposition thickness of each of the one or more wafers.

In some examples, determining whether adjustments to the one or more control components of the process chamber are to be made comprises comparing the predicted characteristics for a given wafer to target characteristics for the given wafer. In some examples, the predicted characteristics comprise virtual metrology measurements.

In some examples, the one or more components of the process chamber comprise one or more valves associated with one or more manifolds of the process chamber, each manifold configured to flow gas to a station of the process chamber. In some examples, the information indicating the status comprises a duration of time each of the one or more valves was open. In some examples, the input based on the obtained information provided to the trained machine learning model comprises an amount of gas provided to a given station operatively coupled to a manifold of the one or more manifolds based on the duration of time a corresponding valve was open. In some examples, the instructions further comprise instructions for determining the amount of gas based on the duration of time the corresponding valve was open and a gas flow rate.

In some examples, the trained machine learning model is configured to take as input at least one of: chamber pressure information; gas pressure information; ampoule temperature; non-ampoule gas feed; or carrier gas flow rate.

In some examples, obtaining the information in (a) occurs at a sampling rate greater than about 100 Hz.

In some examples, the one or more control components comprise one or more divert valves that divert gas flowed through a manifold from a station of the process chamber.

In some examples, the process chamber is a multi-station process chamber, and wherein the adjustments to the one or more control components comprise lowering a flow rate of gas to the first station relative to the flow rate of the gas to the second station.

In some examples, the process chamber is a multi-station process chamber comprising at least a first station and a second station, and wherein the adjustments to the one or more control components comprise changing a radio frequency (RF) power used to generate a plasma associated with the deposition process for the first station relative to the second station.

In some examples, the instructions further comprise instructions for: (e) obtaining post-processing metrology data on at least one wafer of the one or more wafers; and (f) updating the trained machine learning model using the post-processing metrology data. In some examples, the post-processing metrology data comprises at least one of: resistivity data; a mass of thin film grown for the at least one wafer; Fourier-transform infrared (FTIR) spectroscopy peaks; thickness of deposited film on the at least one wafer; refractive index; stress at localized positions on the at least one wafer; stress associated with wafer bow of the at least one wafer; particle information; or material permittivity information.

In some examples, the instructions further comprise instructions for: (e) determining, based on the predicted characteristics, a degradation status of at least one component of the one or more components of the process chamber.

### BRIEF DESCRIPTION OF THE DRAWINGS

FIG. 1 shows a substrate processing apparatus for depositing or etching a film on or over a semiconductor substrate utilizing any number of processes in accordance with some embodiments.

FIG. 2 is a schematic diagram of an example multi-station process chamber in accordance with some embodiments.

FIG. 3 is a schematic diagram that illustrates various control components associated with an example process chamber in accordance with some embodiments.

FIG. 4 is a block diagram of a system for automated control of process chamber components.

FIG. 5 is a flowchart of an example process for automated control of process chamber components.

FIG. 6 presents an example computer system that may be employed to implement certain embodiments described herein.

FIG. 7 illustrates example timing diagrams for control of process chamber components in accordance with some embodiments.

FIG. 8 is a schematic diagram of a system that may be used in conjunction with example techniques for precursor recovery in accordance with some embodiments.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

In some embodiments, control components associated with a process chamber may be actuated to control a fabrication process. For example, in an instance in which the process chamber is a multi-station process chamber, control components associated with individual stations of a multi-station process chamber may be individually actuated such that fabrication processes may be individually controlled within each station. In some embodiments, a fabrication process may be a deposition process, such as an atomic layer deposition (ALD) process, a chemical vapor deposition process (CVD), or the like. In some embodiments, a fabrication process may be an etch process. In some embodiments, a fabrication process may be a passivation process in which a surface composition of a substrate is altered (e.g., using oxidization), for example, to protect sidewalls of a feature of the substrate during a subsequent etch process. In some embodiments, a fabrication process may be an inhibition process during which growth rates are altered at different positions of a feature (e.g. a top of a feature or a bottom of a feature) during deposition.

In some embodiments, control components may be individually actuated for individual stations to provide uniformity across the different stations. For example, individual actuation of the control components may cause a deposition process to be stopped or blocked in a particular station, while the deposition process continues in other stations. By way of example, by blocking deposition in a station associated with a faster growth rate while allowing deposition to continue in other stations with slower growth rates, a more uniform deposition thickness may be achieved across substrates undergoing the deposition process in the different stations. As another example, individual actuation of the control components may cause an etch process to be stopped or blocked in a particular station while allowing the etch process to continue in other stations. By way of example, by blocking the etch process in a station with a faster etch rate while allowing the etch process to continue in other stations with slower etch rates, a more uniform etch depth may be achieved across substrates undergoing the etch process in the different stations. It should be understood that although some embodiments described herein are described with respect to a multi-station process chamber, the techniques described herein may be applied to a single station module. For example, in some implementations, the techniques described herein may be applied in a single station module to divert a particular gas species used in a particular step of a recipe, while allowing additional pulses, time, etc. to be utilized in connection with other steps of the recipe, thereby allowing for control of the fabrication process within the single station. Additionally, it should be understood that the techniques may be applied to plasma-based and non-plasma-based fabrication processes alike. The techniques described herein may be advantageous from an environmental perspective, from a cost and/or resources perspective, and the like. For example, the techniques described herein may be used to save (e.g., by diverting) various process gases, which may be beneficial from an environmental and/or a cost perspective.

In some embodiments, control components may include individual gas flow valves that operatively couple a station to a particular gas source associated with the process chamber. For example, a gas flow valve may be associated with a particular manifold that is used to provide gas from a gas source to a particular station during a fabrication process such that, when the gas flow valve is set to an “open” or “outlet” position, the station receives gas via the manifold, and, when the gas flow valve is set to a “closed” or “divert” position, the station does not receive gas via the manifold. In some embodiments, a first gas flow valve associated with a first station and a second gas flow valve associated with a second station may operatively couple the first station and the second station to a common gas source via a common manifold. By setting the first gas flow valve to a “closed” or “divert” position while setting the second gas flow valve to an “open” or “outlet” position, the first station may be blocked from receiving gas via the manifold while the second station may receive the gas via the manifold. Accordingly, by individual control of the first gas flow valve and the second gas flow valve, the fabrication process may be stopped in the first station while occurring in the second station. Note that similar actuation of gas flow valves may be performed with respect to a single station module, e.g., to control flow of particular gas species during various steps of a multi-step recipe.

In some embodiments, the control components may include individual RF switches that operatively couple a station to an RF generator associated with the multi-station process chamber. For example, a first RF switch associated with a first station may operatively couple the first station to the RF generator, and a second RF switch associated with a second station may operatively couple the second station to the second RF generator. By setting the first RF switch to a “disabled” state while setting the second RF switch to an “enabled” state, the first station may be blocked from receiving RF power from the RF generator while the second station may receive RF power from the RF generator. Accordingly, via individual control of the first RF switch and the second RF switch, a fabrication process may be stopped in the first station while occurring in the second station.

In some implementations, determination of whether to make adjustments to particular control components may be made based on an output of a trained machine learning model. It should be understood that, as used herein, a trained machine learning model may refer to any suitable model type or architecture that is based on model inference, and may include a neural network, a Bayesian inference model, a regression, or the like. The machine learning model may be configured to take, as inputs, status information regarding one or more components of a fabrication tool and generate, as outputs, predicted wafer characteristics of each wafer undergoing fabrication in a different station and/or adjustments to be made to control components in order to generate uniformity across the wafers undergoing fabrication. Note that the machine learning model operates in situ such that actuation of control components in order to produce wafer uniformity occurs during a fabrication process, In some implementations, the status information regarding one or more components may include valve timing information associated with valves of the fabrication tool, and/or information derived from valve timing information. By way of example, the valves may be valves associated with one or more manifolds, each configured to flow gas to a process station. The machine learning model may take, as an input, valve open duration and/or an amount of gas (which may be a precursor gas used in a deposition step, a gas used in an oxidation step, a gas used in a passivation step, a gas used in an inhibition step, and/or any combination thereof) flowed to a particular station, which may be determined based on the valve open duration and the gas flow rate. Because wafer characteristics, such as wafer thickness, may be impacted by the amount of gas flowed to a station in which a wafer is being processed, the machine learning model may be able to predict wafer thickness at a present time based on valve open duration and/or an amount of gas flowed to the station. The predicted wafer characteristics may be considered “virtual metrology” measurements. Such virtual metrology measurements may be used in connection with other applications, e.g., as a proxy for various physical metrology measurements which may be time and/or resource intensive to acquire, which may be destructive to the wafer, etc. Additionally, note that although valve timing information is generally utilized as an example of component measurements that may be used by a machine learning model, other components for which measurements may be utilized as inputs to the machine learning model may include RF related components (such as RF switches, an RF generator, etc.), pressure information, temperature information, flow rate, etc.

The machine learning model may continuously receive status information during a fabrication process such that the machine learning model may responsively generate information which may be used to modify performance of the fabrication process in situ. Rather than relying on a process engineer to, e.g., set a number of deposition cycles for each station prior to a deposition process being performed, the techniques described herein may allow for near real-time in situ control to allow greater uniformity across wafers undergoing a fabrication process in different stations of a multi-station fabrication tool. Additionally, in some embodiments, the machine learning model may be iteratively (e.g., periodically) updated over time thereby allowing for the machine learning model to adapt in conjunction with system drift. For example, in some embodiments, the machine learning model may be updated using post-processing metrology results performed on a subset of wafers. Such updates may be considered “online” updates of the machine learning model. In some embodiments, a trained machine learning model may be utilized as an initial starting point for another machine learning model, e.g., using various transfer learning techniques. For example, transfer learning may be applied to build and/or train another machine learning model utilized in connection with a similar fabrication tool used for a different application.

Certain implementations may be utilized in conjunction with a number of wafer fabrication processes, such as various plasma-enhanced atomic layer deposition (ALD) processes, various plasma-enhanced chemical vapor deposition (CVD) processes, or may be utilized on-the-fly during single deposition processes. In certain implementations, an RF power generator having multiple output ports may be utilized at any signal frequency, such as at frequencies between about 300 kHz and about 60 MHz, which may include frequencies of about 400 kHz, about 1 MHz, about 2 MHz, about 13.56 MHz, and/or about 27.12 MHz. However, in other implementations, RF power generators having multiple output ports may operate at any signal frequency, which may include relatively low frequencies, such as between about 50 kHz and about 300 kHz, as well as higher signal frequencies, such as frequencies between about 60 MHz and about 100 MHz.

It should be noted that although particular implementations described herein may show and/or describe multi-station semiconductor fabrication chambers having 4 (four) process stations, implementations are intended to embrace multi-station integrated circuit fabrication chambers having or utilizing any number of process stations. Thus, in certain implementations, individual output ports of an RF power generator having multiple output ports may be assigned to a process station of a multi-station fabrication chamber having, for example, 2 process stations or 3 process stations. In other implementations individual output ports of an RF power generator having multiple output ports may be assigned to process stations of a multi-station integrated circuit fabrication chamber having a larger number of process stations, such as 5 process stations, 6 process stations, 8 process stations, 10 process stations, or any other number of process stations. Further, embodiments of the disclosure apply to chambers having only a single process station. Additionally, although particular implementations described herein may show and/or describe utilization of a single, relatively low frequency RF signal, such as a frequency of between about 300 kHz and about 2 MHz, as well as a single, relatively high-frequency RF signal, such as a frequency of between about 2 MHz and about 100 MHz, the disclosed implementations are intended to embrace the use of any number of frequencies below about 2 MHz as well as any number of frequencies above about 2 MHz.

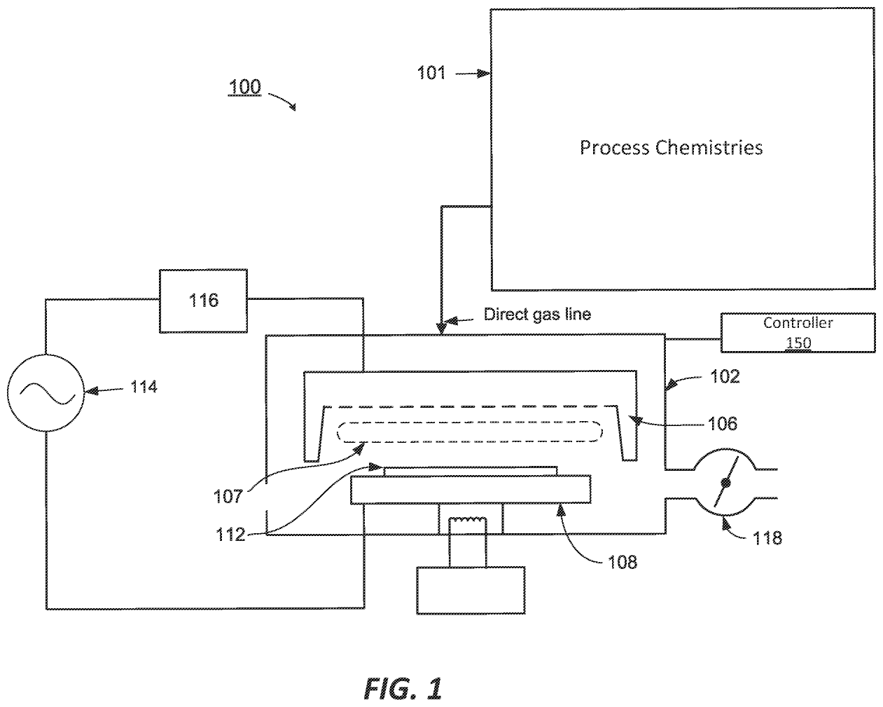

FIG. 1 shows a substrate processing apparatus 100 for depositing films on or over a semiconductor substrate utilizing any number of processes, according to various implementations. Processing apparatus 100 of FIG. 1 may employ a single process station 102 of a process chamber with a single substrate holder 108 (e.g., a pedestal) in an interior volume, which may be maintained under vacuum by vacuum pump 118. Showerhead 106 and gas delivery system 101, which may be fluidically coupled to the process chamber, may permit the delivery of film precursors, for example, as well as carrier and/or purge and/or process gases, secondary reactants, etc. Equipment utilized in the generation of plasma within the process chamber is also shown in FIG. 1. The apparatus schematically illustrated in FIG. 1 may be adapted for performing, in particular, plasma-enhanced CVD.

In some embodiments, gas delivery system 101 may include various components for performing process chemistries, such as a mixing vessel for blending and/or conditioning process gases for delivery to showerhead 106. Particular reactants may be stored in liquid form prior to vaporization and subsequent delivery to process station 102 of a process chamber. Gas delivery system may include components for vaporizing liquid reactant. In some implementations, a liquid flow controller may be provided for controlling a mass flow of liquid for vaporization and delivery to process station 102.

Showerhead 106 may operate to distribute process gases and/or reactants (e.g., film precursors) toward substrate 112 at the process station, the flow of which may be controlled by one or more valves upstream from the showerhead. In the implementation depicted in FIG. 1, substrate 112 is depicted as located beneath showerhead 106, and is shown resting on a single substrate holder 108. Showerhead 106 may include any suitable shape, and may include any suitable number and arrangement of ports for distributing process gases to substrate 112. In some implementations involving 2 or more stations, gas delivery system 101 includes valves or other flow control structures upstream from the showerhead, which can independently control the flow of process gases and/or reactants to each station so as to permit gas flow to one station while prohibiting gas flow to a second station. Furthermore, gas delivery system 101 may be configured to independently control process gases and/or reactants delivered to each station in a multi-station apparatus such that the gas composition provided to different stations is different; e.g., the partial pressure of a gas component may vary between stations at the same time.

In the implementation of FIG. 1, gas volume 107 is depicted as being located beneath showerhead 106. In some implementations, single substrate holder 108 may be raised or lowered to expose substrate 112 to gas volume 107 and/or to vary the size of gas volume 107. Optionally, single substrate holder 108 may be lowered and/or raised during portions of the deposition process to modulate process pressure, reactant concentration, etc., within gas volume 107. Showerhead 106 and single substrate holder 108 are depicted as being electrically coupled to RF signal generator 114 and matching network 116 for coupling power to a plasma generator. Thus, showerhead 106 may function as an electrode for coupling radio frequency power into process station 102. In some implementations, the plasma energy is controlled (e.g., via a system controller having appropriate machine-readable instructions and/or control logic) by controlling one or more of a process station pressure, a gas concentration, power output of an RF signal generator, and so forth. For example, RF signal generator 114 and matching network 116 may be operated at any suitable RF power level, which may operate to form plasma having a desired composition of radical species. In addition, RF signal generator 114 may provide RF power having more than one frequency component, such as a low-frequency component (e.g., less than about 2 MHz) as well as a high frequency component (e.g., greater than about 2 MHz).

In some implementations, plasma ignition and maintenance conditions are controlled with appropriate hardware and/or appropriate machine-readable instructions in a system controller which may provide control instructions via a sequence of input/output control instructions. In one example, the instructions for bringing about ignition or maintaining a plasma are provided in the form of a plasma activation portion of a process recipe. In some cases, process recipes may be sequentially arranged, so that at least some instructions for the process can be executed concurrently. In some implementations, instructions for setting one or more plasma parameters may be included in a recipe preceding a plasma ignition process. For example, a first recipe may include instructions for setting a flow rate of an inert (e.g., helium) and/or a reactant gas, instructions for setting a plasma generator to a power set point and time delay instructions for the first recipe. A second, subsequent recipe may include instructions for enabling the plasma generator and time delay instructions for the second recipe. A third recipe may include instructions for disabling the plasma generator and time delay instructions for the third recipe. It will be appreciated that these recipes may be further subdivided and/or iterated in any suitable way within the scope of the present disclosure. In some deposition processes, a duration of a plasma strike may correspond to a duration of a few seconds, such as from about 3 seconds to about 15 seconds, or may involve longer durations, such as durations of up to about 30 seconds, for example. In certain implementations described herein, much shorter plasma strikes may be applied during a processing cycle. Such plasma strike durations may be on the order of less than about 50 milliseconds, with about 25 milliseconds being utilized in a specific example.

In some embodiments, instructions for a controller 150 may be provided via input/output control (IOC) sequencing instructions. In one example, the instructions for setting conditions for a process phase may be included in a corresponding recipe phase of a process recipe. In some cases, process recipe phases may be sequentially arranged, so that all instructions for a process phase are executed concurrently with that process phase. In some embodiments, instructions for setting one or more reactor parameters may be included in a recipe phase. For example, a first recipe phase may include instructions for setting a flow rate of an inert and/or a reactant gas (e.g., the first precursor), instructions for setting a flow rate of a carrier gas (such as argon), instructions for setting a first RF power level, and time delay instructions for the first recipe phase. A second, subsequent recipe phase may include instructions for modulating or stopping a flow rate of an inert and/or a reactant gas, instructions for modulating a flow rate of a carrier or purge gas, instructions for setting a second RF power level, and time delay instructions for the second recipe phase. A third recipe phase may include instructions for modulating a flow rate of a second reactant gas, instructions for modulating the duration of flow of the second reactant gas, instructions for modulating the flow rate of a carrier or purge gas, instructions for setting a third RF power level, and time delay instructions for the third recipe phase. A fourth, subsequent recipe phase may include instructions for modulating or stopping a flow rate of an inert and/or a reactant gas, and instructions for modulating a flow rate of a carrier or purge gas, instructions for setting a fourth RF power level, and time delay instructions for the fourth recipe phase. It will be appreciated that these recipe phases may be further subdivided and/or iterated in any suitable way within the scope of the disclosed embodiments.

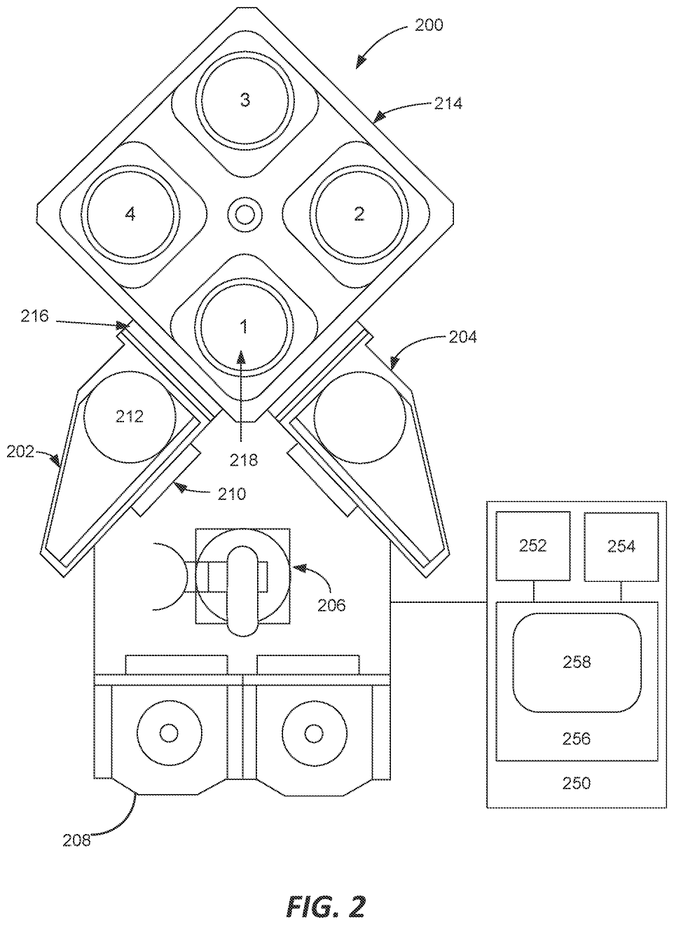

As described above, one or more process stations may be included in a multi-station processing tool. FIG. 2 shows a schematic view of an embodiment of a multi-station processing tool 200 with an inbound load lock 202 and an outbound load lock 204, either or both of which may include a remote plasma source. A robot 206 at atmospheric pressure is configured to move wafers from a cassette loaded through a pod 208 into inbound load lock 202 via an atmospheric port 210. A wafer is placed by the robot 206 on a substrate holder 212 in the inbound load lock 202, the atmospheric port 210 is closed, and the load lock is pumped down. Where the inbound load lock 202 includes a remote plasma source, the wafer may be exposed to a remote plasma treatment in the load lock prior to being introduced into a process chamber 214. Further, the wafer also may be heated in the inbound load lock 202 as well, for example, to remove moisture and adsorbed gases. Next, a chamber transport port 216 to process chamber 214 is opened, and another robot (not shown) places the wafer into the reactor on a substrate holder of a first station shown in the reactor for processing. While the embodiment depicted in FIG. 2 includes load locks, it will be appreciated that, in some embodiments, direct entry of a wafer into a process station may be provided.

The depicted process chamber 214 includes four process stations, numbered from 1 to 4 in the embodiment shown in FIG. 2. Each station has a heated substrate holder (shown at 218 for station 1), and gas line inlets. It will be appreciated that in some embodiments, each process station may have different or multiple purposes. For example, in some embodiments, a process station may be switchable between an ALD and plasma-enhanced ALD process mode. Additionally or alternatively, in some embodiments, process chamber 214 may include one or more matched pairs of ALD and plasma-enhanced ALD process stations. While the depicted process chamber 214 includes four stations, it will be understood that a process chamber according to the present disclosure may have any suitable number of stations. For example, in some embodiments, a process chamber may have five or more stations, while in other embodiments a process chamber may have three or fewer stations.

It should be understood that the various references to RF power settings of the present disclosure are generally intended, unless otherwise indicated, to refer to the RF power setting per wafer. In embodiments involving multiple process stations in a multi-station processing tool, one or more RF power sources may be provided that serve multiple process stations (e.g., simultaneously and/or sequentially). In embodiments in which a single RF power source serves multiple process stations, the per-wafer power setting of the RF power source may be multiplied by the number of process stations being simultaneously provided with plasma at a desired power level. In other words, when the present disclosure describes an RF power setting of 300 watts, it should be understood that the RF power setting reflects a per-wafer value of 300 watts and that, in multi-station processing tools, the actual RF power setting of the RF power source may be the per-wafer power setting multiplied by the number of stations.

Multi-station processing tool 200 may include a wafer handling system for transferring wafers within process chamber 214. In some embodiments, the wafer handling system may transfer wafers between various process stations and/or between a process station and a load lock. It will be appreciated that any suitable wafer handling system may be employed. Non-limiting examples include wafer carousels and wafer handling robots. FIG. 2 also depicts an embodiment of a system controller 250 employed to control process conditions and hardware states of multi-station processing tool 200. System controller 250 may include one or more memory devices 256, one or more mass storage devices 254, and one or more processors 252. Processor 252 may include a CPU or computer, analog, and/or digital input/output connections, stepper motor controller boards, etc.

In some embodiments, system controller 250 controls all of the activities of multi-station processing tool 200. System controller 250 executes system control software 258 stored in mass storage device 254, loaded into memory device 256, and executed on processor 252, Alternatively, the control logic may be hard coded in the system controller 250. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software 558 may include instructions for controlling the timing, mixture of gases, gas flow rates, chamber and/or station pressure, chamber and/or station temperature, wafer temperature, target power levels, RF power levels, substrate holder, chuck and/or susceptor position, and other parameters of a particular process performed by multi-station processing tool 200. System control software 258 may be configured in any suitable way. For example, various process tool component subroutines or control objects may be written to control operation of the process tool components used to carry out various process tool processes. System control software 258 may be coded in any suitable computer readable programming language.

In some embodiments, system control software 258 may include input/output control (IOC) sequencing instructions for controlling the various parameters described above. Other computer software and/or programs stored on mass storage device 254 and/or memory device 256 associated with system controller 250 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto substrate holder 218 and to control the spacing between the substrate and other parts of multi-station processing tool 200.

A process gas control program may include code for controlling gas composition (e.g., iodine-containing silicon precursor gases, and nitrogen-containing gases, carrier gases and purge gases as described herein) and flow rates and optionally for flowing gas into one or more process stations prior to deposition in order to stabilize the pressure in the process station. A pressure control program may include code for controlling the pressure in the process station by regulating, for example, a throttle valve in the exhaust system of the process station, a gas flow into the process station, etc.

A heater control program may include code for controlling the current to a heating unit that is used to heat the substrate. Alternatively, the heater control program may control delivery of a heat transfer gas (such as helium) to the substrate.

A plasma control program may include code for setting RF power levels applied to the process electrodes in one or more process stations in accordance with the embodiments herein.

A pressure control program may include code for maintaining the pressure in the reaction chamber in accordance with the embodiments herein.

In some embodiments, there may be a user interface associated with system controller 250. The user interface may include a display screen, graphical software displays of the apparatus and/or process conditions, and user input devices such as pointing devices, keyboards, touch screens, microphones, etc.

In some embodiments, parameters adjusted by system controller 250 may relate to process conditions. Non-limiting examples include process gas composition and flow rates, temperature, pressure, plasma conditions (such as RF bias power levels), etc. These parameters may be provided to the user in the form of a recipe, which may be entered utilizing the user interface.

Signals for monitoring the process may be provided by analog and/or digital input connections of system controller 250 from various process tool sensors. The signals for controlling the process may be output on the analog and digital output connections of multi-station processing tool 200. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

System controller 250 may provide program instructions for implementing the above-described deposition processes. The program instructions may control a variety of process parameters, such as DC power level, RF bias power level, pressure, temperature, etc. The instructions may control the parameters to operate in-situ deposition of film stacks according to various embodiments described herein.

The system controller 250 will typically include one or more memory devices 256 and one or more processors configured to execute the instructions so that the apparatus will perform a method in accordance with disclosed embodiments. Machine-readable media containing instructions for controlling process operations in accordance with disclosed embodiments may be coupled to the system controller 250.

In some implementations, the system controller 250 is part of a system, which may be part of the above-described examples. Such systems can include semiconductor processing, equipment, including a processing tool or tools, chamber or chambers, a platform or platforms for processing, and/or specific processing components (a wafer holder, a gas flow system, etc.). These systems may be integrated with electronics for controlling their operation before, during, and after processing of a semiconductor wafer or substrate. The electronics may be referred to as the “controller,” which may control various components or subparts of the system or systems. The system controller 250, depending on the processing conditions and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 250 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the system controller 250 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The system controller 250, in some implementations, may be a part of or coupled to a computer that is integrated with, coupled to the system, otherwise networked to the system, or a combination thereof. For example, the system controller 250 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 250 receives instructions in the form of data, which specify parameters for each of the processing steps to be performed during one or more operations. It should be understood that the parameters may be specific to the type of process to be performed and the type of tool that the system controller 250 is configured to interface with or control. Thus as described above, the system controller 250 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an PEALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the system controller 250 might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

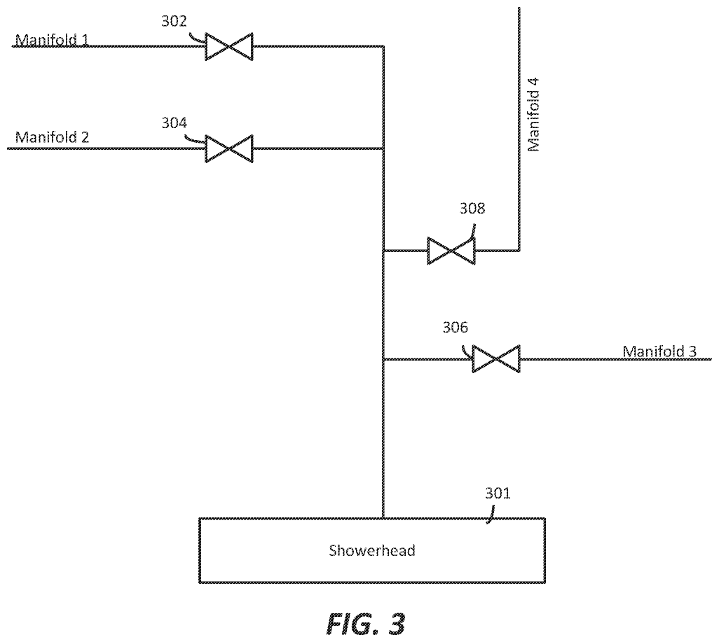

It should be noted that FIG. 2 depicts merely one example of a multi-station process chamber that may be used in some embodiments of the techniques, systems, and methods described herein. In some implementations, a multi-station process chamber may include multiple chambers or reactors (e.g., two, four, six, eight, etc.), where the multiple chambers or reactors are modular in nature and are clustered. For example, the multiple chambers or reactors may be clustered around one or more shared components, such as one or more wafer handling systems, a system controller, etc. The multiple chambers or reactors may be under a common vacuum environment. In some embodiments, the vacuum environment, and the multiple modules it encloses, as well as the shared wafer handling resources, is collectively referred to as “a cluster tool.” In some implementations, a station is operatively coupled to components (e.g., one or more manifolds each coupled to a gas source, an RF generator, etc.). In instances in which a process chamber is a multi-station process chamber, some components may be commonly shared. For example, each station may be coupled via one or more manifolds to common gas sources. As another example, the RF generator may be common to all stations. In some embodiments, a station may be operatively coupled to a common component via an individually controllable component. For example, a station may be operatively coupled to a manifold via a gas valve. More particularly, a first station may be operatively coupled to the manifold via a first gas valve, and a second station may be operatively coupled to the manifold via a second gas valve, where the first gas valve and the second gas valve may be independently controlled and/or actuated. As described above, these individually controllable components may be actuated based on outputs of a machine learning model in order to achieve greater wafer-to-wafer uniformity across stations of a multi-station apparatus. Described below and shown in connection with FIG. 3 are examples of individually controllable valves which may serve as control targets based on outputs of a machine learning model. Moreover, the measurements associated with the valves may be used as inputs to the machine learning model. For example, valve open and close timing information may be used to determine an amount of gas flowed to a particular station. The machine learning model may take, as input, the amount of gas flowed to the station and generate predicted wafer characteristics at a given time based on the amount of gas flowed to the station over a time window corresponding to the given time.

In some embodiments, a multi-station process chamber is associated with one or more manifolds, where each manifold may be coupled to a different gas source. Different manifolds may be used in association with different fabrication processes. For example, a first manifold may be used for gas flow during a deposition process. As another example, a second manifold may be used for gas flow during an etch process and/or during an inhibition process. As used herein, an inhibition process refers to adjusting growth rates within features during, for example, an ALD process. For example, an inhibition process may be used to prevent growth from occurring at a top of a feature while allowing growth to occur at a bottom of a feature. As yet another example, a third manifold may be used during oxidation steps and a fourth manifold may be used during reduction steps. In a more particular example, the third manifold and/or the fourth manifold may be used during a passivation process. As used herein, a passivation process may be used to change the surface composition of a film or substrate, for example, the prevent etching of sidewalls of a feature. As still another example, a manifold may be used to provide gases (e.g., a non-reactive gas such as Argon) in connection with a purge step, where the gas(es) are utilized to remove volatile byproducts. Such a manifold may be shared amongst multiple stations of a process chamber.

In some embodiments, corresponding valves may have a naming convention that indicates that the corresponding valves may operatively couple a particular manifold to different stations. For example, a valve X01 may operatively couple station X to a particular manifold. As a more particular example, in some embodiments, a multi-station process chamber that includes four stations may include valves x101, x201, x301, and x401, where valve x101 operatively couples station 1 to the manifold, valve x201 operatively couples station 2 to the manifold, and so on. It should be understood that a process chamber may include any suitable number of individually controllable valves (e.g., four, eight, sixteen, twenty, etc.).

FIG. 3 shows a schematic diagram of an example coupling of various manifolds to a single station of a multi-station process chamber in accordance with some embodiments. As illustrated, multiple manifolds are coupled to a showerhead 301. For example, Manifold 1 is operatively coupled to showerhead 301 via a valve 302, Manifold 2 is operatively coupled to showerhead 301 via a valve 304, Manifold 3 is operatively coupled to showerhead 301 via a valve 306, and Manifold 4 is operatively coupled to showerhead 301 via a valve 308. As described below, in some embodiments, each of valves 302, 304, 306, and 308 may be individually actuated separately from the corresponding valves associated with other stations of the multi-station process chamber. In some embodiments, each manifold may be operatively coupled to a different gas source. For example, Manifold 1 may be used to provide a first gas via a first gas source to the station, and Manifold 2 may be used to provide a second gas via a second gas source to the station. In some embodiments, different manifolds may be used in connection with different fabrication processes. Additionally or alternatively, in some embodiments, multiple manifolds may be during performance of a single fabrication process. Although four manifolds are depicted in FIG. 3, it should be understood that a station may be operatively coupled to any suitable number of manifolds. Moreover, although only four valves are depicted in FIG. 3 for simplicity, it should be understood that a process chamber may include any suitable number of valves (e.g., four, eight, sixteen, twenty, etc.).

In some implementations, a trained machine learning model may be utilized to take, as inputs, tool control information measured from a fabrication tool in operation, e.g., during performance of a fabrication operation (e.g. a deposition operation). The tool control information may indicate status of one or more components of the fabrication tool (e.g., of a multi-station process chamber). For example, the one or more components may include valves associated with one or more manifolds configured to deliver various gases to a station. In some embodiments, each valve may be associated with a particular manifold and station. It should be noted that, in some embodiments, the one or more components of the fabrication tool may include multiple valves such that data (e.g., measurements) associated with multiple manifolds and/or multiple stations of the process chamber is utilized as inputs to the trained machine learning model. As a more particular example, the measurements may include open and close times (e.g., timepoints corresponding to times the valve was opened and closed). The open and close times may be used to determine, based on the valve open duration, an amount of gas delivered via the corresponding manifold to a given station. It should be noted that, in such instances, the input to the trained machine learning model may include information derived from the valve open and close times, such as a calculated amount of gas delivered to the station based on the valve timing information. In such instances, the amount of gas may be determined based on a known gas flow rate and the valve timing information. In some implementations, the amount of gas may be determined based on the valve timing information, the gas flow rate, and other information, such as ampoule pressure, partial pressure, or any combination thereof. As another example, the one or more components may include RF switches that couple RF power from an RF generator to each station. In some embodiments, the measurements may include measurements from one or more sensors associated with the process chamber. The sensors may include one or more camera sensors, one or more pressure sensors, one or more temperature sensors, one or more voltage sensors, one or more current sensors, one or more spectroscopy sensors, or any combination thereof.

In some embodiments, the trained machine learning model may be configured to generate, as an output, adjustments to one or more control components of the fabrication tool. It should be noted that the one or more control components may be the same as (or include one or more of) the one or more components associated with the measurements used as inputs to the machine learning model, or the one or more control components may be different from the one or more components. For example, in an instance in which the one or more components used to provide input to the machine learning model include a first valve associated with a first manifold (e.g., that provides a first gas to a particular station), the one or more control components to which adjustments may be made may include the first valve, may include a second valve (e.g., associated with a second manifold that provides a second gas to the station, or provides the second gas to a different station other than the station for which model input measurements were made), an RF switch, and/or any suitable combination thereof. As a more particular example, in some implementations, the one or more control components may include one or more divert valves associated with a particular manifold that causes gas to be diverted from a given station. The adjustments to the one or more control components may thereby cause a change in a fabrication process occurring in a first station of the multi-station process chamber relative to a second station of the multi-station process chamber. For example, the adjustments to the one or more control components may cause an RF power to a particular station to be changed (e.g., increased or decreased) thereby affecting a rate of a deposition process in the station, may cause a precursor gas to be diverted away from a particular station thereby stopping a deposition process in the station, may cause a change in a gas flow rate (e.g., an increase or a decrease) of a gas toward a particular station thereby affecting a rate of a deposition process in the station, or the like. Note that in instances in which the fabrication apparatus is a single station module, rather than controlling station-to-station variability, adjustments to the one or more control components may allow granular control of individual process steps being performed in the station, for example, by modulating gas flow of a particular species, adaptively changing a number of pulses or time allotted to a particular step, or the like.

It should be noted that a trained machine learning model may be configured to generate, as an output, adjustments to one or more control components directly. Additionally or alternatively, the trained machine learning model may be configured to generate predicted wafer characteristics based on the measured status information associated with the one or more components. Continuing with this example, adjustments to the one or more control components may be made based on the predicted wafer characteristics. The predicted wafer characteristics may include a predicted wafer thickness at a given time based on the measurements associated with the one or more components. For example, wafer thickness for a wafer in a given station may be predicted based on an amount of gas delivered to the station, which may in turn be determined based on valve timing of a valve associated with the manifold that delivers the gas to the station. Additionally, it should be noted that the machine learning model may be configured to consider, or take as additional inputs, other information associated with the process chamber, such as chamber pressure, gas pressure, ampoule temperature, non-ampoule gas feed information, carrier gas flow rate, camera data from one or more cameras that obtain visual information from stations of the process chamber, data from one or more sensors (e.g., temperature sensors, voltage sensors, current sensors, spectral sensors, etc) or the like.

The machine learning model may be of any suitable type and/or architecture. Example types of machine learning models that may be used include a regression model (e.g., a linear regression model, a logistic regression model, etc.), a neural network, a deep neural network, a convolutional neural network (CNN) regressor, a network that utilizes Bayesian optimization, or the like. Additionally, it should be noted that, in some implementations, the machine learning model may be periodically updated, e.g., as “online” updates to the model. For example, the machine learning model may be updated based on post-processing metrology obtained using a subset of processed wafers. As a more particular example, the machine learning model may be re-trained using training set constructed using known component information (e.g., known valve timing information, known RF power information, etc.) and wafer thicknesses measured using various metrology techniques. The metrology techniques may include one or more of: a mass of thin film grown for the at least one wafer; Fourier-transform infrared (FTIR) spectroscopy peaks; thickness of deposited film on the at least one wafer; refractive index; stress at localized positions on the at least one wafer; stress associated with wafer bow of the at least one wafer; particle information; and/or material permittivity information. It should be noted that, in some implementations, the machine learning model may be trained to predict any of these metrology measurements. Such predictions, generally referred to herein as predicted wafer characteristics, may be considered “virtual metrology” measurements.

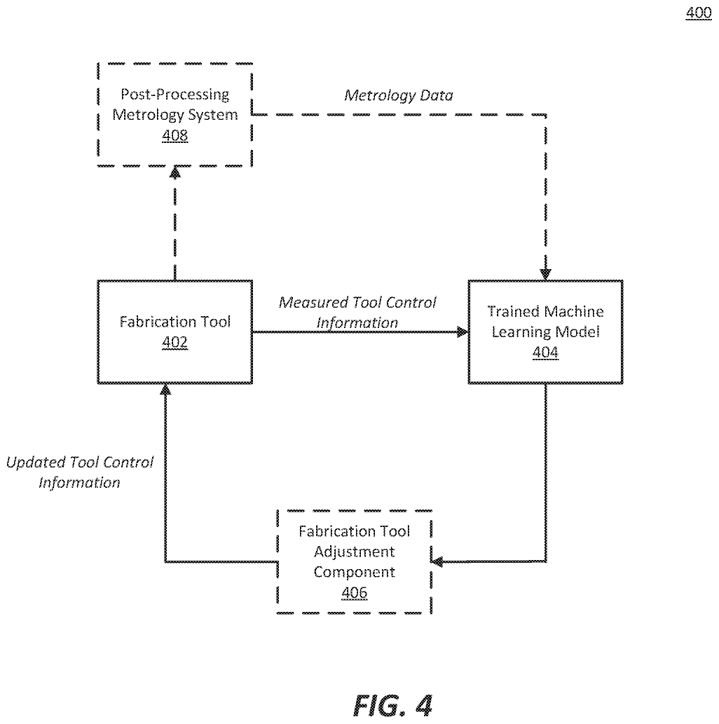

FIG. 4 is a schematic diagram of a system 400 for automated control of process chamber components in accordance with some implementations. As illustrated, system 400 includes a fabrication tool 402, a trained machine learning model 404, and a fabrication tool adjustment component 406. As described above, fabrication tool 402 may be a multi-station process chamber configured to perform various deposition and/or etch processes. As illustrated in FIG. 4, trained machine learning model 404 may be configured to take, as an input, measured tool control information, which may include valve timing information, RF power information, RF switch information, or the like. In some embodiments, trained machine learning model 404 may generate, as an output, predicted wafer characteristics at a present time (e.g., based on the measured tool control information at the present time). The predicted wafer characteristics may include predicted wafer thicknesses for wafers in each station of the process chamber (e.g., fabrication tool 402). In such implementations, the output of trained machine learning model 404 may be provided to fabrication tool adjustment component 406, which may be configured to determine adjustments to one or more control components of fabrication tool 402 in order to produce uniformity across the wafers undergoing processing in fabrication tool 402. For example, as described above, the adjustments may include actuating one or more divert valves that divert gas from one or more stations, modifying a gas flow rate for a gas being flowed to one or more stations, modifying an RF power provided to one or more stations, or the like. Alternatively, in some embodiments, the machine learning model may determine the one or more adjustments directly. In such embodiments, fabrication tool adjustment component 406 may be omitted.

Additionally, as illustrated in FIG. 4, a post-processing metrology system 408 may be configured to determine metrology information for a subset of wafers processed by fabrication tool 402. The metrology results may then be used to update trained machine learning model 404, e.g., by re-training trained machine learning model 404. Accordingly, trained machine learning model 404 may be periodically updated using post-processing metrology data.

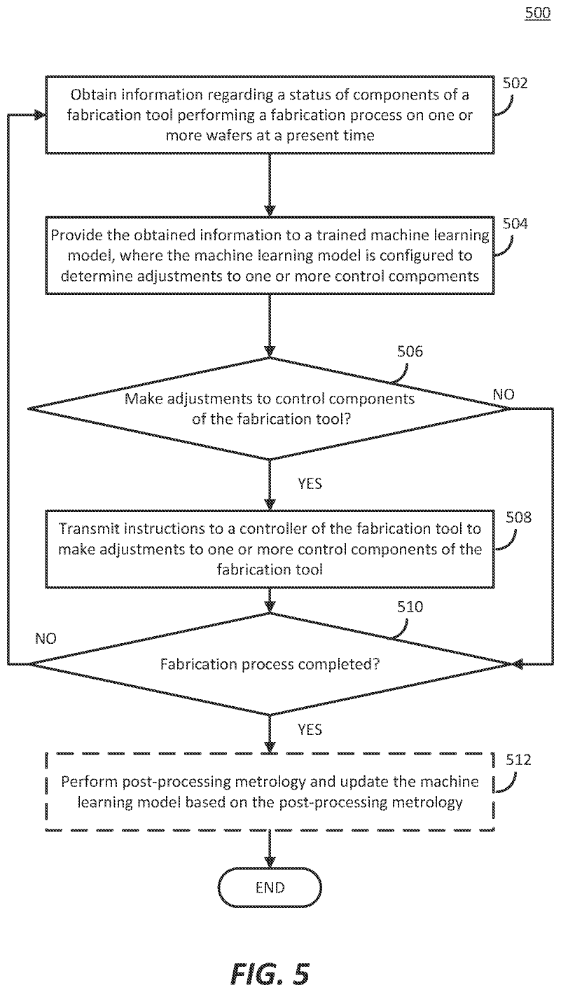

FIG. 5 is a flowchart of an example process for automated control of components of a process chamber in accordance with some embodiments. In some implementations, blocks of process 500 may be executed by a processor or a controller, such as a controller associated with the process chamber. In some embodiments, process 500 may be executed by an independent edge node controller configured to communicate with the tool controller or processor. It should be understood that although some embodiments described below in connection with process 500 are with respect to a multi-station process chamber, blocks of process 500 may be executed in connection with a single station module. In some embodiments, two or more blocks of process 500 may be executed substantially in parallel. In some implementations, one or more blocks of process 500 may be omitted. In some implementations, blocks of process 500 may be performed in an order other than what is shown in FIG. 5.

Process 500 can begin at 502 by obtaining information regarding a status of components of a fabrication tool performing a fabrication process on one or more wafers at a present time. As described above, the information may include valve timing information. For example, the valve timing information may include valve open and close times for one or more valves of the multi-station process chamber. As a more particular example, the one or more valves may be valves associated with one or more manifolds, where each manifold delivers a particular gas to a station of the multi-station process chamber (e.g., as described above in connection with FIG. 3). As a specific example, the one or more valves may be valves associated with manifolds configured to deliver precursor gas to various stations. It should be understood that, in some embodiments, multiple sets of valves, each set of valves associated with manifolds configured to deliver a particular type of gas (e.g., precursor gas, gas utilized for an oxidation step, gas utilized for an inhibition step, gas utilized for a passivation step, etc.), may be considered. In instances in which the information includes valve timing information, the valve timing information may be obtained at any suitable rate, e.g., 10 Hz, 50 Hz, 100 Hz, 200 Hz, 800 Hz, 1000 Hz, 1500 Hz, 2000 Hz, or the like. In some embodiments, the information regarding the status of components may additionally or alternatively include pressure information (e.g., chamber pressure information, relative ampoule pressure information, gas pressure information, etc.), RF power information (e.g., RF switch timing information, RF power delivered to each station, etc.), temperature information, or any combination thereof.

At 504, process 500 can provide the obtained information to a trained machine learning model. The obtained information, or information derived from the obtained information, may be provided as inputs to the trained machine learning model. For example, in an instance in which the obtained information includes valve timing information, the information provided to the machine learning model may include an amount of a particular gas provided to a given station over a duration of time corresponding to the time at which the information was obtained at block 502. In some implementations, the machine learning model may generate, as an output, a predicted wafer thickness of a wafer in a given station. For example, for a process chamber comprising four stations, each having a wafer undergoing a deposition process, the machine learning model may output a predicted wafer thickness for each wafer. In some embodiments, the machine learning model may generate, as an output, values of one or more control components and/or changes to current settings of the one or more control components in order to generate uniformity in wafer thickness across wafers in multiple stations of the process chamber. For example, the output may indicate that gas flow to a particular station is to be decreased and/or diverted because the wafer in the station has a predicted thickness exceeding that of wafers in the other stations, that an RF power to a particular station is to be reduced because the wafer in the station has a predicted thickness exceeding that of wafers in the other stations, or the like.

At 506, process 500 can determine whether to make adjustments to control components of the fabrication tool. For example, in some embodiments, process 500 can determine that adjustments are to be made responsive to outputs of the machine learning model (e.g., generated at block 504) indicating that two wafers in two stations are predicted to have wafer thicknesses at the present time that differ by more than a predetermined threshold. As another example, in some embodiments, in instances in which the machine learning model directly generates parameters for the control components that are likely to provide uniformity across the wafers, process 500 can determine whether to make adjustments to control components of the fabrication tool directly based on the machine learning model output.

If, at 506, process 500 determines that adjustments are not to be made to the control components (“no” at 506), process 500 can proceed to 510. Conversely, if, at 506, process 500 determines that adjustments are to be made to the control components (“yes” at 506), process 500 can proceed to block 508 and can transmit instructions to a controller of the fabrication tool to make adjustments to the one or more control components of the fabrication tool. As described above, the adjustments may cause: gas to be diverted from a particular station (e.g., in instances in which the fabrication tool includes a common mass flow controller for all stations); a gas flow rate to be modified (e.g., lowered or increased) in instances in which a separate mass flow controller is used; an RF power delivered to a particular station to be modified; or any combination thereof.

At 510, process 500 can determine whether the fabrication process has been completed. For example, for a deposition process, process 500 may determine whether a maximum number of deposition cycles (e.g., set in a recipe being implemented) have been performed, whether a predicted wafer thickness for all wafers undergoing fabrication have reached a target thickness, or the like. Note that, in instances in which process 500 determines that a specified maximum number of deposition cycles have been performed but that the predicted wafer thickness has not reached the target thickness, process 500 can cause an alert to be presented or transmitted that flags an error condition associated with the fabrication tool.

If, at 510, process 500 determines that the fabrication process has been completed (“yes” at 510), process 500 can end. Conversely, if, at 510, process 500 determines that the fabrication process has not been completed (“no” at 510), process 500 can loop back to 502 and can obtain updated information at a next time step. Process 500 may loop through blocks 502-510 until the fabrication process has been completed.

In some implementations, the techniques described herein may be utilized to determine a degradation of at least one component of a multi-station process chamber. The determined degradation may then be used to perform predictive maintenance such that the at least one component may be replaced prior to failure without replacing other components that are not experiencing degradation. By way of example, using conventional techniques, it may not be possible to determine which valve of a set of valves used in a tool are failing. Accordingly, conventionally, all of the valves may be replaced on a periodic and/or pre-determined schedule (e.g., after a set period of time, after a set number of processes have been run, etc.), regardless of whether a given valve is degrading. However, using the techniques described herein, a particular valve may be identified as experiencing more than a predetermined amount of degradation and/or likely to imminently fail, and the identified valve may be replaced while retaining the other valves. This may allow for substantial cost savings, as only components that are identified as experiencing degradation are replaced, rather than replacing all components regardless of current status. In some implementations, components may be identified as experiencing degradation based on the machine learning model outputs. For example, in some embodiments, a particular station of a multi-station process chamber may be identified as having components experiencing degradation based on the machine learning model outputs.

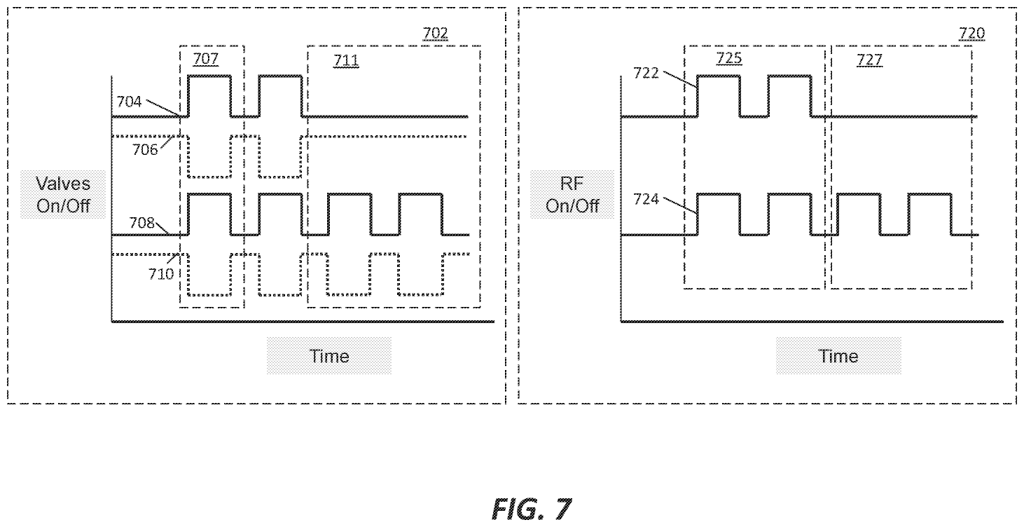

FIG. 7 illustrates example timing diagrams for control of chamber components in accordance with some embodiments. Referring to panel 702, timing diagrams for supply valves and divert valves for different stations are illustrated. In particular, curve 704 illustrates timing for a supply valve for a first station, and curve 706 illustrates timing for a divert valve for the first station. Note that curves 704 and 706 are inverted with respect to each other, because while the supply valve is open, the divert valve is closed, and vice versa. Similarly, curve 708 illustrates timing for a supply valve for a second station, and curve 710 illustrates timing for a divert valve for the second station. Panel 707 denotes a single cycle. Note that during the cycle highlighted in panel 707, the supply valves for both stations are open while the divert valves are closed. Referring to panel 711, curve 704 illustrates that the supply valve for the first station is closed (e.g., because a target deposition thickness has been reached) and curve 706 illustrates that the divert valve for the first station is open. However, during the same time, curves 708 and 710 illustrate that the supply valve for the second station and the divert valve for the second station continue to cycle between open and closed to allowed for additional deposition cycles, even when deposition cycles in the first station have finished.

A similar concept is illustrated in the timing diagrams shown in panel 720. Curves 722 and 724 illustrates timing diagrams for an RF switch that toggles RF power on and off for a first station and a second station, respectively. As illustrated, during a first time period 725, RF power is toggled on and off for a set of cycles for both the first station and the second station. During a second time period 727, the RF switch for the first station remains off (as illustrated by curve 722), e.g., due to the target thickness being reached for a wafer undergoing processing in the first station. However, during second time period 727, RF power continues to cycle on and off for the second station (as illustrated by curve 724) as deposition cycles continue in the second station.

Note that although the timing diagrams shown in FIG. 7 are described above as corresponding to a first station and a second station, in some embodiments, multiple stations may follow the same timing. For example, referring to curve 722, stations 1, 2, and 3 may follow the timing illustrated by curve 722, whereas station 4 may follow the timing illustrated by curve 724.

As described above, e.g., in connection with FIGS. 1, 5, and 7, in some embodiments, a precursor supply valve may be closed and a divert valve may be opened for one or more stations that have reached a target deposition thickness, while other stations continue to undergo deposition cycles. In some embodiments, the diverted precursor gas (and/or any other gases) may be recovered, filtered, and recycled. By recycling and re-using diverted precursor gas (or any other suitable gas), a substantial cost savings may be realized. In some embodiments, the diverted precursor gas may be diverted to a precursor recovery tank by causing a recovery valve to open that causes diverted precursor gas to flow from the divert line to the precursor recovery tank. The recovery valve may be opened automatically (e.g., without user input) responsive to a determination that one or more stations have finished processing steps. The diverted precursor gas may be filtered to, e.g., separate carrier gas from precursor gas by a filter.

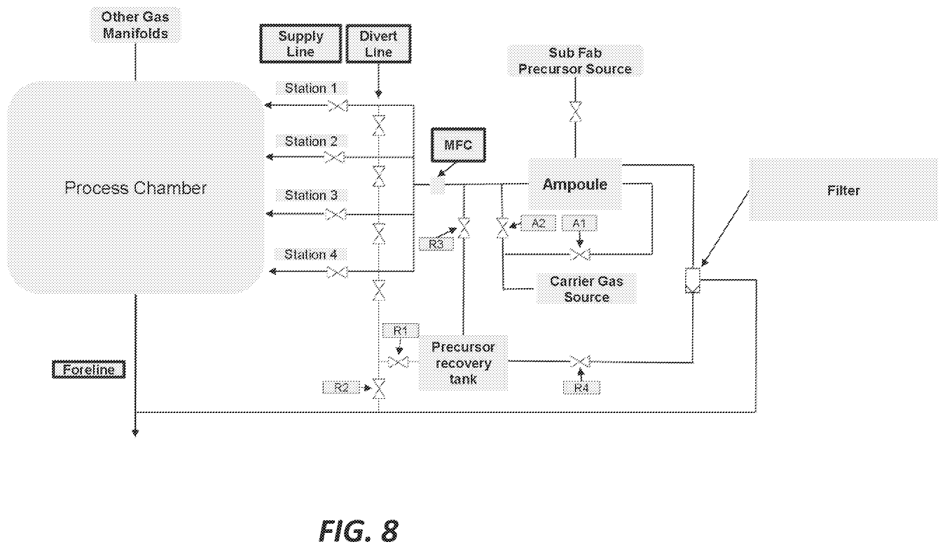

FIG. 8 illustrated an example schematic diagram of a system that may be used for precursor gas recovery. In the system shown in FIG. 8, when processing has completed in one or more stations, precursor gas may be diverted via the divert line. Responsive to determining that processing has completed in one or more stations and is ongoing in at least one other station, valve R1 may be opened, allowing precursor gas from the divert line to flow to the precursor recovery tank. Once processing has completed in all stations, valve R3 may close and recovery valve R4 may open, thereby allowing diverted precursor gas to flow to the membrane filter. The filter may be configured to filter carrier gas to the fore-line and to recover the precursor gas to the ampoule. In instances in which valve Al is closed and valve A2 is open, thereby bypassing the ampoule, valve R2 may be opened and valve RI may be closed to prevent carrier gas not containing precursor from entering the recovery tank.

### Context for Disclosed Computational Embodiments

Systems including fabrication tools as described herein may include logic for automated control of components.

The analysis logic may be designed and implemented in any of various ways. For example, the logic can be implemented in hardware and/or software. Examples are presented in the controller section herein. Hardware-implemented control logic may be provided in any of a variety of forms, including hard coded logic in digital signal processors, application-specific integrated circuits, and other devices that have algorithms implemented as hardware. Analysis logic may also be implemented as software or firmware instructions configured to be executed on a general-purpose processor. System control software may be provided by “programming” in a computer readable programming language.

The computer program code for controlling processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded. Integrated circuits used in logic may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated in the form of various individual settings (or program files), defining operational parameters for carrying out a particular analysis or image analysis application.

In some implementations, the image analysis logic is resident (and executes) on a computational resource on or closely associated with a fabrication tool from which camera images are captured. In some implementations, the image analysis logic is remote from a fabrication tool from which camera images are captured. For example, the analysis logic may be executable on cloud-based resources.

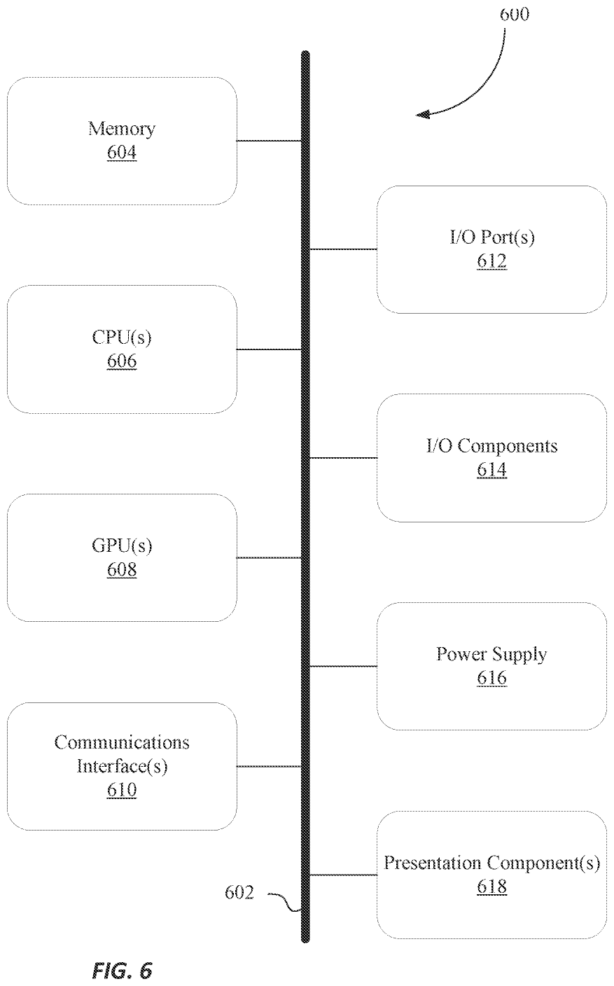

FIG. 6 is a block diagram of an example of the computing device 600 suitable for use in implementing some embodiments of the present disclosure. For example, device 600 may be suitable for implementing some or all functions of image analysis logic disclosed herein.

Computing device 600 may include a bus 602 that directly or indirectly couples the following devices: memory 604, one or more central processing units (CPUs) 606, one or more graphics processing units (GPUs) 608, a communication interface 1310, input/output (I/O) ports 612, input/output components 614, a power supply 616, and one or more presentation components 618 (e.g., display(s)). In addition to CPU 606 and GPU 608, computing device 600 may include additional logic devices that are not shown in FIG. 6, such as but not limited to an image signal processor (ISP), a digital signal processor (DSP), an ASIC, an FPGA, or the like.

Although the various blocks of FIG. 6 are shown as connected via the bus 602 with lines, this is not intended to be limiting and is for clarity only. For example, in some embodiments, a presentation component 618, such as a display device, may be considered an I/O component 614 (e.g., if the display is a touch screen). As another example, CPUs 606 and/or GPUs 608 may include memory (e.g., the memory 604 may be representative of a storage device in addition to the memory of the GPUs 608, the CPUs 606, and/or other components). In other words, the computing device of FIG. 6 is merely illustrative. Distinction is not made between such categories as “workstation,” “server,” “laptop,” “desktop,” “tablet,” “client device,” “mobile device,” “hand-held device,” “electronic control unit (ECU),” “virtual reality system,” and/or other device or system types, as all are contemplated within the scope of the computing device of FIG. 6.

Bus 602 may represent one or more busses, such as an address bus, a data bus, a control bus, or a combination thereof. The bus 602 may include one or more bus types, such as an industry standard architecture (ISA) bus, an extended industry standard architecture (EISA) bus, a video electronics standards association (VESA) bus, a peripheral component interconnect (PCI) bus, a peripheral component interconnect express (PCIe) bus, and/or another type of bus.

Memory 604 may include any of a variety of computer-readable media. The computer-readable media may be any available media that can be accessed by the computing device 600. The computer-readable media may include both volatile and nonvolatile media, and removable and non-removable media. By way of example, and not limitation, the computer-readable media may comprise computer-storage media and/or communication media.

The computer-storage media may include both volatile and nonvolatile media and/or removable and non-removable media implemented in any method or technology for storage of information such as computer-readable instructions, data structures, program modules, and/or other data types. For example, memory 604 may store computer-readable instructions (e.g., that represent a program(s) and/or a program element(s), such as an operating system. Computer-storage media may include, but is not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other medium which can be used to store the desired information and which can be accessed by computing device 600. As used herein, computer storage media does not comprise signals per se.

The communication media may embody computer-readable instructions, data structures, program modules, and/or other data types in a modulated data signal such as a carrier wave or other transport mechanism and includes any information delivery media. The term “modulated data signal” may refer to a signal that has one or more of its characteristics set or changed in such a manner as to encode information in the signal. By way of example, and not limitation, the communication media may include wired media such as a wired network or direct-wired connection, and wireless media such as acoustic, RF, infrared and other wireless media. Combinations of any of the above should also be included within the scope of computer-readable media.

CPU(s) 606 may be configured to execute the computer-readable instructions to control one or more components of the computing device 600 to perform one or more of the methods and/or processes described herein. CPU(s) 606 may each include one or more cores (e.g., one, two, four, eight, twenty-eight, seventy-two, etc.) that are capable of handling a multitude of software threads simultaneously. CPU(s) 606 may include any type of processor and may include different types of processors depending on the type of computing device 600 implemented (e.g., processors with fewer cores for mobile devices and processors with more cores for servers). For example, depending on the type of computing device 600, the processor may be an ARM processor implemented using Reduced Instruction Set Computing (RISC) or an x86 processor implemented using Complex Instruction Set Computing (CISC). Computing device 600 may include one or more CPUs 1306 in addition to one or more microprocessors or supplementary co-processors, such as math co-processors.

GPU(s) 608 may be used by computing device 600 to render graphics (e.g., 3D graphics). GPU(s) 608 may include many (e.g., tens, hundreds, or thousands) of cores that are capable of handling many software threads simultaneously, GPU(s) 608 may generate pixel data for output images in response to rendering commands (e.g., rendering commands from CPU(s) 606 received via a host interface). GPU(s) 608 may include graphics memory, such as display memory, for storing pixel data. The display memory may be included as part of memory 604. GPU(s) 608 may include two or more GPUs operating in parallel (e.g., via a link). When combined, each GPU 608 can generate pixel data for different portions of an output image or for different output images (e.g., a first GPU for a first image and a second GPU for a second image). Each GPU can include its own memory or can share memory with other GPUs.

In examples where the computing device 600 does not include the GPU(s) 608, the CPU(s) 606 may be used to render graphics.

Communication interface 610 may include one or more receivers, transmitters, and/or transceivers that enable computing device 600 to communicate with other computing devices via an electronic communication network, included wired and/or wireless communications. Communication interface 610 may include components and functionality to enable communication over any of a number of different networks, such as wireless networks (e.g., Wi-Fi, Z-Wave, Bluetooth, Bluetooth LE, ZigBee, etc.), wired networks (e.g., communicating over Ethernet), low-power wide-area networks (e.g., LoRaWAN, SigFox, etc.), and/or the internet.

I/O ports 612 may enable the computing device 1300 to be logically coupled to other devices including I/O components 614, presentation component(s) 618, and/or other components, some of which may be built in to (e.g., integrated in) computing device 600. Illustrative I/O components 614 include a microphone, mouse, keyboard, joystick, track pad, satellite dish, scanner, printer, wireless device, etc. I/O components 614 may provide a natural user interface (NUI) that processes air gestures, voice, or other physiological inputs generated by a user. In some instances, inputs may be transmitted to an appropriate network element for further processing. An NUI may implement any combination of speech recognition, stylus recognition, facial recognition, biometric recognition, gesture recognition both on screen and adjacent to the screen, air gestures, head and eye tracking, and touch recognition (as described in more detail below) associated with a display of computing device 600. Computing device 600 may be include depth cameras, such as stereoscopic camera systems, infrared camera systems, RGB camera systems, touchscreen technology, and combinations of these, for gesture detection and recognition. Additionally, computing device 600 may include accelerometers or gyroscopes (e.g., as part of an inertia measurement unit (IMU)) that enable detection of motion. In some examples, the output of the accelerometers or gyroscopes may be used by computing device 600 to render immersive augmented reality or virtual reality.

Power supply 616 may include a hard-wired power supply, a battery power supply, or a combination thereof. Power supply 616 may provide power to computing device 600 to enable the components of computing device 600 to operate.

Presentation component(s) 618 may include a display (e.g., a monitor, a touch screen, a television screen, a heads-up-display (HUD), other display types, or a combination thereof), speakers, and/or other presentation components. Presentation component(s) 618 may receive data from other components (e.g., GPU(s) 608, CPU(s) 606, etc.), and output the data (e.g., as an image, video, sound, etc.).

The disclosure may be described in the general context of computer code or machine-useable instructions, including computer-executable instructions such as program modules, being executed by a computer or other machine, such as a personal data assistant or other handheld device. Generally, program modules including routines, programs, objects, components, data structures, etc., refer to code that perform particular tasks or implement particular abstract data types. The disclosure may be practiced in a variety of system configurations, including hand-held devices, consumer electronics, general-purpose computers, more specialty computing devices, etc. The disclosure may also be practiced in distributed computing environments where tasks are performed by remote-processing devices that are linked through a communications network.

### Additional Considerations

Without limitation, example systems may include a plasma etch chamber or module, a plasma-assisted deposition chamber or module such as a plasma-assisted chemical vapor deposition (PECVD) chamber or module or a plasma-assisted atomic layer deposition (PEALD) chamber or module, an atomic layer etch (ALE) chamber or module, a clean chamber or module, a physical vapor deposition (PVD) chamber or module, an ion implantation chamber or module, and any other plasma-assisted semiconductor processing systems that may be associated or used in the fabrication and/or manufacturing of semiconductor wafers.

Unless otherwise specified, the plasma power levels and associated parameters provided herein are appropriate for processing a 300 mm wafer substrate. One of ordinary skill in the art would appreciate that these parameters may be adjusted as necessary for substrates of other sizes.

The apparatus/process described herein may be used in conjunction with lithographic patterning tools or processes, for example, for the fabrication or manufacture of electronic devices including semiconductor devices, displays, LEDs, photovoltaic panels and the like. Typically, though not necessarily, such tools/processes will be used or conducted together in a common fabrication facility. Lithographic patterning of a film typically includes some or all of the following operations, each operation enabled with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

As used in this specification and appended claims, the singular forms “a”, “an”, and “the” include plural referents unless the content and context dictates otherwise. For example, reference to “a cell” includes a combination of two or more such cells. Unless indicated otherwise, an “or” conjunction is used in its correct sense as a Boolean logical operator, encompassing both the selection of features in the alternative (A or B, where the selection of A is mutually exclusive from B) and the selection of features in conjunction (A or B, where both A and B are selected).

It is to be understood that the phrases “for each <item> of the one or more <items>,” “each <item> of the one or more <items>,” or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite the fact that dictionary definitions of “each” frequently define the term to refer to “every one of two or more things”) and would not imply that there must be at least two of those items. Similarly, the term “set” or “subset” should not be viewed, in itself, as necessarily encompassing a plurality of items—it will be understood that a set or a subset can encompass only one member or multiple members (unless the context indicates otherwise). The use, if any, of ordinal indicators, e.g., (a), (b), (c) . . . or the like, in this disclosure and claims is to be understood as not conveying any particular order or sequence, except to the extent that such an order or sequence is explicitly indicated. For example, if there are three steps labeled (i), (ii), and (iii), it is to be understood that these steps may be performed in any order (or even concurrently, if not otherwise contraindicated) unless indicated otherwise. For example, if step (ii) involves the handling of an element that is created in step (i), then step (ii) may be viewed as happening at some point after step (i). Similarly, if step (i) involves the handling of an element that is created in step (ii), the reverse is to be understood. It is also to be understood that use of the ordinal indicator “first” herein, e.g., “a first item,” should not be read as suggesting, implicitly or inherently, that there is necessarily a “second” instance, e.g., “a second item.”

Various computational elements including processors, memory, instructions, routines, models, or other components may be described or claimed as “configured to” perform a task or tasks. In such contexts, the phrase “configured to” is used to connote structure by indicating that the component includes structure (e.g., stored instructions, circuitry, etc.) that performs the task or tasks during operation. As such, the unit/circuit/component can be said to be configured to perform the task even when the specified component is not necessarily currently operational (e.g., is not on).

The components used with the “configured to” language may refer to hardware—for example, circuits, memory storing program instructions executable to implement the operation, etc. Additionally, “configured to” can refer to generic structure (e.g., generic circuitry) that is manipulated by software and/or firmware (e.g., an FPGA or a general-purpose processor executing software) to operate in manner that is capable of performing the recited task(s). Additionally, “configured to” can refer to one or more memories or memory elements storing computer executable instructions for performing the recited task(s). Such memory elements may include memory on a computer chip having processing logic. In some contexts, “configured to” may also include adapting a manufacturing process (e.g., a semiconductor fabrication facility) to fabricate devices (e.g., integrated circuits) that are adapted to implement or perform one or more tasks.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method for deposition control in a process chamber, the method comprising:
(a) obtaining, at a present time, information indicating a status of one or more components of the process chamber during performance of a deposition process on one or more wafers, wherein the deposition process comprises a plurality of deposition cycles performed in the process chamber;
(b) determining whether adjustments to one or more control components of the process chamber are to be made by providing an input based on the obtained information to a trained machine learning model configured to determine adjustments as an output, wherein the adjustments to the one or more control components cause a change in the deposition process;
(c) responsive to determining that adjustments to the one or more control components are to be made, transmitting instructions to a controller of the process chamber that cause the adjustments to the one or more control components to be implemented; and
(d) repeating (a)-(c) until the deposition process has been completed.

2. The method of claim 1, wherein the process chamber is a multi-station process chamber.

3. The method of claim 2, wherein the adjustments to the one or more control components cause a change in the deposition process occurring in a first station of the multi-station process chamber relative to a second station of the multi-station process chamber.

4. The method of claim 2, wherein in (d), (a)-(c) are repeated until the deposition has been completed in each station of the multi-station process chamber.

5. The method of claim 1, wherein the process chamber is a single station process chamber.

6. The method of claim 1, wherein the machine learning model is configured to determine the adjustments based at least in part on a determination of predicted wafer characteristics of the one or more wafers undergoing the deposition process at the present time.

7. The method of claim 6, wherein the predicted characteristics of the one or more wafers comprise a deposition thickness of each of the one or more wafers.

8. The method of claim 1, wherein determining whether adjustments to the one or more control components of the process chamber are to be made comprises comparing the predicted characteristics for a given wafer to target characteristics for the given wafer.

9. The method of claim 8, wherein the predicted characteristics comprise virtual metrology measurements.

10. The method of claim 1, wherein the one or more components of the process chamber comprise one or more valves associated with one or more manifolds of the process chamber, each manifold configured to flow gas to a station of the process chamber.

11. The method of claim 10, wherein the information indicating the status comprises a duration of time each of the one or more valves was open.

12. The method of claim 11, wherein the input based on the obtained information provided to the trained machine learning model comprises an amount of gas provided to a given station operatively coupled to a manifold of the one or more manifolds based on the duration of time a corresponding valve was open.

13. The method of claim 12, further comprising determining the amount of gas based on the duration of time the corresponding valve was open and a gas flow rate.

14. The method of claim 1, wherein the trained machine learning model is configured to take as input at least one of: chamber pressure information; gas pressure information; ampoule temperature; non-ampoule gas feed; or carrier gas flow rate.

15. The method of claim 1, wherein obtaining the information in (a) occurs at a sampling rate greater than about 100 Hz.

16. The method of claim 1, wherein the one or more control components comprise one or more divert valves that divert gas flowed through a manifold from a station of the process chamber.

17. The method of claim 16, further comprising flowing diverted precursor gas to a precursor recovery tank by causing a recovery valve to be opened responsive to determining the one or more divert valves have been opened.

18. The method of claim 17, further comprising:
causing the diverted precursor gas to be filtered; and
recycling the filtered diverted precursor gas for use in subsequent process steps performed in the process chamber.

19. The method of claim 1, wherein the process chamber is a multi-station process chamber, and wherein the adjustments to the one or more control components comprise lowering a flow rate of gas to the first station relative to the flow rate of the gas to the second station.

20. The method of claim 1, wherein the process chamber is a multi-station process chamber comprising at least a first station and a second station, and wherein the adjustments to the one or more control components comprise changing a radio frequency (RF) power used to generate a plasma associated with the deposition process for the first station relative to the second station.

21. The method of claim 1, further comprising:
(e) obtaining post-processing metrology data on at least one wafer of the one or more wafers; and
(f) updating the trained machine learning model using the post-processing metrology data.

22. The method of claim 21, wherein the post-processing metrology data comprises at least one of: resistivity data; a mass of thin film grown for the at least one wafer; Fourier-transform infrared (FTIR) spectroscopy peaks; thickness of deposited film on the at least one wafer; refractive index; stress at localized positions on the at least one wafer;
stress associated with wafer bow of the at least one wafer; particle information; or material permittivity information.

23. The method of claim 1, further comprising:
(e) determining, based on the predicted characteristics, a degradation status of at least one component of the one or more components of the process chamber.

24. A computer program product comprising a non-transitory computer readable medium on which is provided computer executable instructions for causing a computational system to perform a method for deposition control in a process chamber, wherein the instructions comprise instructions for:
(a) obtaining, at a present time, information indicating a status of one or more components of the process chamber during performance of a deposition process on one or more wafers, wherein the deposition process comprises a plurality of deposition cycles performed in the process chamber;
(b) determining whether adjustments to one or more control components of the process chamber are to be made by providing an input based on the obtained information to a trained machine learning model configured to determine adjustments as an output, wherein the adjustments to the one or more control components cause a change in the deposition process;
(c) responsive to determining that adjustments to the one or more control components are to be made, transmitting instructions to a controller of the process chamber that cause the adjustments to the one or more control components to be implemented; and
(d) repeating (a)-(c) until the deposition process has been completed.

25. The computer program product of claim 24, wherein the process chamber is a multi-station process chamber.

26. The computer program product of claim 25, wherein the adjustments to the one or more control components cause a change in the deposition process occurring in a first station of the multi-station process chamber relative to a second station of the multi-station process chamber.

27. (canceled)

28. (canceled)

29. (canceled)

30. (canceled)

31. The computer program product of claim 24, wherein determining whether adjustments to the one or more control components of the process chamber are to be made comprises comparing the predicted characteristics for a given wafer to target characteristics for the given wafer.

32. (canceled)

33. The computer program product of claim 24, wherein the one or more components of the process chamber comprise one or more valves associated with one or more manifolds of the process chamber, each manifold configured to flow gas to a station of the process chamber.

34. (canceled)

35. (canceled)

36. (canceled)

37. (canceled)

38. (canceled)

39. The computer program product of claim 24, wherein the one or more control components comprise one or more divert valves that divert gas flowed through a manifold from a station of the process chamber.

40. The computer program product of claim 24, wherein the process chamber is a multi-station process chamber, and wherein the adjustments to the one or more control components comprise lowering a flow rate of gas to the first station relative to the flow rate of the gas to the second station.

41.-44. (Canceled)
